(19) United States
(12) Patent Application Publication
(10) Pub. No.: US 2020/0255929 A1
(43) Pub. Date: Aug. 13, 2020

(54) METHOD FOR PRODUCING AN ELECTRICALLY CONDUCTIVE FOIL

(71) Applicant: Fraunhofer-Gesellschaft zur Förderung der angewandten Forschung e.V., Munich (DE)

(72) Inventors: Nicolas Schiller, Stolpen (DE); Steffen Straach, Dresden (DE); Matthias Fahland, Dresden (DE); Cindy Steiner, Dresden (DE); Sebastian Rethberg, Dresden (DE)

(73) Assignee: Fraunhofer-Gesellschaft zur Förderung der angewandten Forschung e.V., Munich (DE)

(21) Appl. No.: 16/640,302

(22) PCT Filed: Aug. 8, 2018
(86) PCT No.: PCT/EP2018/071564

§ 371 Date: Feb. 19, 2020

(30) Foreign Application Priority Data
Aug. 23, 2017 (DE) 10 2017 119 308.1

(51) Int. Cl. C23C 14/00; C01B 3/50; C23C 14/56; C23C 14/16

(52) U.S. Cl. CPC C23C 14/0005; C23C 14/165; C23C 14/56; C01B 3/505

(57) ABSTRACT

A method is provided for producing a foil made of an electrically conductive material. The foil consists of the same electrically conductive material along the extension of the foil thickness. A flexible substrate is first introduced into a working chamber; a layer made of the electrically conductive material is deposited on at least one surface region of the flexible substrate using a vacuum coating process; and the first layer is then removed from the flexible substrate. Either an ion-etching process is carried out at least on the surface region of the flexible substrate prior to depositing the layer made of the electrically conductive material and/or the layer made of the electrically conductive material is heated during and/or after the layer is deposited.

### CROSS-REFERENCE TO RELATED APPLICATIONS

This application is a 371 nationalization of international patent application PCT/EP2018/071564 filed Aug. 8, 2018, which claims priority under 35 USC § 119 to German patent application 10 2017 119 308.1 filed Aug. 23, 2017. The entire contents of each of the above-identified applications are hereby incorporated by reference.

### BRIEF DESCRIPTION OF THE DRAWINGS

The figures show:

FIG. 1 a schematic illustration of a device for carrying out steps of the method according to the invention,

FIG. 2 a schematic illustration of an alternative device for carrying out steps of the method according to the invention.

### DETAILED DESCRIPTION

The invention relates to a method for producing an electrically conductive foil. A foil in the sense of the invention refers to a flat, self-supporting and flexible structure having a maximum thickness of 1.5 mm and made of a material that is homogeneous across its surface and does not lose its essential material properties even after repeated bending or rolling.

A variety of methods for producing electrically conductive foils have been established. For example, electrically conductive foils can be produced by mechanically rolling an electrically conductive starting material. These types of production processes are limited by the minimum achievable thickness of such a foil. Copper foils having a minimum thickness of about 6 μm can be produced using rolling processes, for example, but this is not thin enough for certain applications. Another disadvantage is that the surfaces of the foils are often scored by the rolling process.

For the production of electrically conductive foils having a foil thickness of less than 6 μm, for example, layer systems comprising electrically conductive material are deposited on flexible substrates using vacuum processes and the flexible substrate is subsequently removed. DE 10 2015 003 369 A1 proposes first depositing a sacrificial layer onto a carrier substrate, and then a wear layer of electrically conductive material onto a carrier substrate, using vacuum coating processes. The layer system produced in this way is then exposed to laser beams, for example, which causes cracks to form in the sacrificial layer and allows the wear layer to be separated from the carrier substrate. The disadvantage of this is that, even after the wear layer has separated from the carrier substrate, remnants of the sacrificial layer remain stuck to the wear layer, which necessitates additional cleaning steps for an electrically conductive foil produced in this way.

From WO 2017/054889 A1 it is known, for reasons of stability, to first deposit a layer composite consisting of at least two layers of different materials onto a flexible substrate using vacuum coating processes. Lithium can be deposited as the first layer, for example, and copper as the second layer. The flexible substrate is then removed from the layer composite. However, this procedure can only be used to produce a foil composite consisting of at least two different materials.

The underlying technical problem of the invention is therefore to create a method for producing an electrically conductive foil, by means of which the disadvantages of the state of the art can be overcome. The method according to the invention should in particular also make it possible to produce an electrically conductive foil having with a foil thickness of less than 1 μm. The foil should furthermore consist of only one material when viewed across the thickness of the foil.

In the method according to the invention for producing a foil made of an electrically conductive material, wherein the foil consists of the same material along the extension of the foil thickness, a flexible substrate is first placed into a working chamber. A layer of the electrically conductive material is then deposited onto at least one surface region of the substrate using a vacuum coating process. For this, an electrically conductive material can be used which, for example, comprises at least one of the chemical elements from the group consisting of copper, indium, aluminum, tin, zinc, magnesium, and silver. The method according to the invention is particularly suitable for producing copper foils. Magnetron sputtering and/or evaporation are particularly suitable as the vacuum coating process for depositing the first layer of the electrically conductive material, and metal foils (in particular made of stainless steel), plastic foils, glass or paper are suitable as the flexible substrate.

After the deposition of the first layer of the electrically conductive material, the first layer is peeled off of the flexible substrate using mechanical means. It has been surprisingly been shown that a single layer of an electrically conductive material deposited directly onto a flexible substrate using vacuum coating processes can be mechanically peeled off of the flexible substrate, if the adhesive force between the flexible substrate and the deposited layer is set such that said adhesive force is lower than the binding forces within the deposited layer and lower than the binding forces within the flexible substrate.

According to the invention, an adhesive force between the flexible substrate and the deposited layer required for peeling is set by carrying out an ion etching process on at least the surface region of the flexible substrate on which the layer of electrically conductive material is to be deposited. The ion etching cleans the substrate surface region and also changes the surface structure of the substrate, which then has a beneficial effect on subsequent method steps. The ions used for ion etching can, for example, originate from a hollow cathode plasma or a magnetron plasma.

The ion etching process presumably creates a surface roughness on the substrate, which makes the mechanical peeling of the single layer of electrically conductive material off of the flexible substrate possible.

Additionally or alternatively to the ion etching of the substrate prior to the deposition of the layer, the layer of electrically conductive material can be heated during and/or after deposition of the layer, which reduces the adhesive force between the flexible substrate and the deposited layer and thus makes the peeling of the deposited layer off of the flexible substrate possible. For this purpose, it is also possible to deposit the layer of electrically conductive material in at least two sublayers, for example, whereby a first sublayer of the layer is deposited using a first vacuum coating process and a second sublayer of the layer is deposited using a second vacuum coating process, whereby the second vacuum coating process is associated with a stronger heat development than the first vacuum coating process.

The procedure according to the invention also allows the mechanical peeling of the flexible substrate if, prior to peeling off of the flexible substrate, a second layer of a different material is deposited onto the layer of electrically conductive material or also multiple layers of a different material are deposited onto the layer of electrically conductive material.

The method according to the invention is particularly suitable for producing electrically conductive foils having a foil thickness of less than 3 μm. Using the method according to the invention, it was even possible to produce electrically conductive foils (in particular copper foils) having a foil thickness of less than 1 μm.

The present invention is explained in more detail below using design examples.

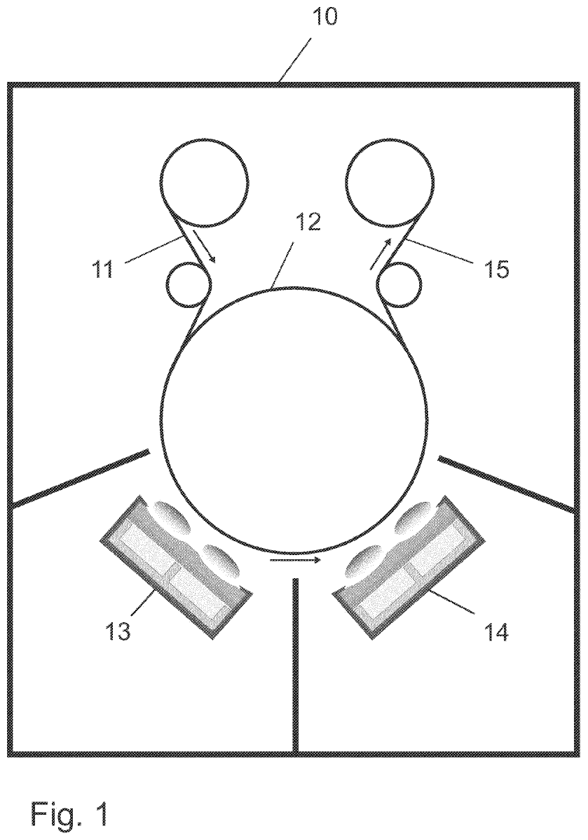

FIG. 1 schematically shows a device, by means of which steps of the method according to the invention can be carried out. A ribbon-like flexible substrate 11 configured as a plastic foil is first placed into a vacuum working chamber 10 in such a way that, after being unwound from an unwinding roller and guided past one or more deflection rollers, it partially wraps around a cooling roller 12. As the flexible substrate 11 is moved along the circumference of the cooling roller in a roll-to-roll process, the flexible substrate passes through two process stations. The first process station includes a magnetron 13, which generates a magnetron plasma in an oxygen-containing atmosphere. The magnetron 13 is operated with known process parameters in such a way that no sputtering material is removed from the magnetron 13 and settles on the flexible substrate 12, and only the oxygen ions from the magnetron plasma are accelerated towards the substrate surface to thereby carry out an ion etching process on the substrate surface. This cleans the surface of the flexible substrate 11 and also changes the structure of the substrate surface.

The second process station, which follows the first process station when viewed in the direction of movement of the substrate 11, includes a magnetron 14 with a copper target. The magnetron 14 uses known process steps to dust copper particles off of the copper target, which then settle on the flexible substrate 11 as a copper layer. The magnetron 14 can preferably be operated in such a way that a copper layer having a layer thickness from the two-digit nanometer range to the single-digit micrometer range is deposited on the flexible substrate 11. After the copper layer has been deposited, the composite 15, which consists of the flexible substrate 11 and the copper layer, is guided past one or more deflection rollers and then wound onto a winding roller.

After the ribbon-like flexible substrate 11 has been completely coated with a copper layer, the roller with the composite 15 is removed from the working chamber 10 and the copper layer is mechanically peeled off of the flexible substrate 11 which is configured as a plastic foil. For this purpose, the roller on which the composite 15 is wound can, for example, be placed onto a smooth base. The front of the ribbon-like composite 15 is unwound a little from the roller and placed onto the smooth base with the substrate side of the composite facing down. Shortly before the end of the ribbon of composite 15, a sharp cutting tool is used to cut through the copper layer at right angles to the direction of the ribbon without cutting through the substrate 11. If the composite 15 is bent along the cut line in the direction of the side of the substrate 11, a beginning can be found at which the copper layer can be peeled off of the plastic foil by hand. The ends of the thus obtained separated plastic foil and copper layer can subsequently be wound onto separate rollers in a ribbon winding machine and the copper layer can then be peeled off of the flexible substrate 11 along the entire ribbon-like composite 15 by the ribbon winding machine. This results in an electrically conductive foil wound on a roller, which consists of the same material along the extension of the foil thickness; in this design example, copper.

The previously described peeling of the copper layer off of the flexible substrate 11 at the front of the composite 15 by hand is described here merely as an example. There are also devices, with which the copper layer can be peeled off of the flexible substrate 11 from the front of the composite 15 as well.

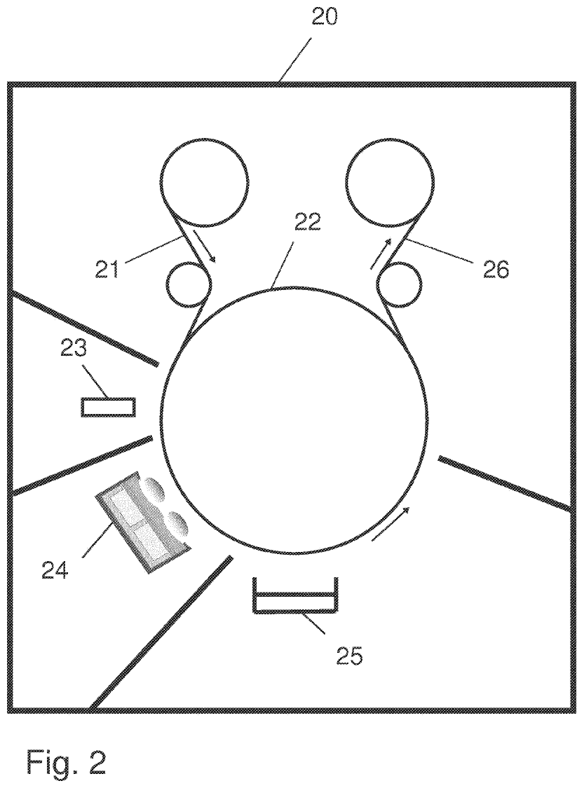

FIG. 2 schematically shows an alternative device with which the method according to the invention can be carried out. A ribbon-like flexible substrate 21 configured as a stainless steel foil is first placed into a working chamber 20 in such a way that, after being unwound from an unwinding roller and guided past one or more deflection rollers, it partially wraps around a cooling roller 22. As the flexible substrate 21 is moved along the circumference of the cooling roller in a roll-to-roll process, the flexible substrate 21 passes through three process stations. The first process station includes a hollow cathode assembly 23, with which a hollow cathode plasma is generated. The ions from the hollow cathode plasma are accelerated toward the substrate surface and thus carry out an ion etching process on the substrate surface. This cleans the surface of the flexible substrate 21 and also changes the structure of the substrate surface.

The second process station, which follows the first process station when viewed in the direction of movement of the substrate 21, includes a magnetron 24 with a copper target. The magnetron 24 uses known process steps to dust copper particles off of the copper target, which then settle on the flexible substrate 21 as a first copper sublayer. The magnetron 24 can preferably be operated in such a way that the first copper sublayer is deposited on the flexible substrate 21 with a layer thickness in the two-digit nanometer range.

After the first copper sublayer has been deposited, the substrate 21 is guided past a third process station. This includes a vessel 25, in which copper is evaporated, which settles on the substrate 24 as a second copper sublayer. In one embodiment, a second copper sublayer is deposited with a layer thickness in the two-digit nanometer range or the single-digit micrometer range. Processes of thermal evaporation, for example, in which all the copper in the vessel 25 is heated, or processes of evaporation using an electron beam, are suitable for the evaporation of the copper in the vessel 25.

It is known that evaporation processes typically involve greater heat development than magnetron sputtering, which heats a substrate to be coated and the layers already on it. In the method according to the invention, the evaporation process causes the flexible substrate 21 and the first copper sublayer to be heated to about 300° C. This leads to a structural change in the first copper sublayer, which is accompanied by a reduction in the adhesive strength of the first copper sublayer on the flexible substrate 21 and has a beneficial effect on subsequent process steps. The procedure described in the second design example is therefore particularly advantageous for producing electrically conductive foils from materials which have a similar or even lower melting point than copper. Therefore, in one embodiment of the invention, an electrically conductive material is used which contains at least one of the chemical elements from the group copper, indium, aluminum, tin, zinc, magnesium, silver.

After the second copper sublayer has been deposited, the composite 26, which consists of the flexible substrate 21 and the first and second copper sublayer, is guided past one or more deflection rollers and then wound onto a winding roller.

After the ribbon-like flexible substrate 21 has been completely coated with the first and second copper sublayer, the roller with the composite 26 is removed from the working chamber 20 and the copper layer, which consists of the first and second copper sublayer, is mechanically peeled off of the flexible substrate 21 which is configured as a stainless steel foil. For this purpose, the roller on which the composite 26 is wound can, for example, be placed onto a smooth base. The front of the ribbon-like composite 26 is unwound a little from the roller and placed onto the smooth base with the stainless steel side of the composite facing down. Shortly before the end of the ribbon of composite 26, a sharp cutting tool is used to cut through the copper layer at right angles to the direction of the ribbon without cutting through the stainless steel foil. If the composite 26 is bent along the cut line in the direction of the side of the stainless steel foil, a beginning can be found at which the copper layer can be peeled off of the stainless steel foil by hand. The ends of the thus obtained separated stainless steel foil and copper layer can subsequently be wound onto separate rollers in a ribbon winding machine and the copper layer can then be peeled off of the flexible substrate 21 along the entire ribbon-like composite 26 by the ribbon winding machine. This results in an electrically conductive foil wound on a roller, which consists of the same material along the extension of the foil thickness; in this design example, copper. In the second design example described above, the second and third process station were components of one and the same system. The method according to the invention according to the second design example can alternatively also be carried out if the second and third process station are components of separate systems.

To clarify the use of and to hereby provide notice to the public, the phrases “at least one of <A>, <B>, . . . and <N>” or “at least one of <A>, <B>, <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. A method for producing a foil made of an electrically conductive material, wherein the foil consists of the same electrically conductive material along the thickness of the foil, the method comprising:
placing a flexible substrate into a working chamber;
depositing a layer of the electrically conductive material onto at least one surface region of the flexible substrate using a vacuum coating process; and
peeling the layer off of the flexible substrate; wherein
either
an ion etching process is performed at least on the surface region of the flexible substrate prior to depositing the layer of the electrically conductive material,
and/or
the layer of the electrically conductive material is heated during and/or after the layer is deposited.

2. The method of claim 1, wherein a metal foil is used as the flexible substrate.

3. The method of claim 2, wherein a stainless steel foil is used as the flexible substrate.

4. The method of claim 1, wherein a plastic foil is used as the flexible substrate.

5. The method of claim 1, wherein glass or paper is used as the flexible substrate.

6. The method of claim 1, wherein the layer is deposited by evaporation.

7. The method of claim 1, wherein the layer is deposited by magnetron sputtering.

8. The method of claim 1, wherein a first sublayer of the layer is deposited by a first vacuum coating process and a second sublayer of the layer is deposited by a second vacuum coating process, wherein the second vacuum coating process is associated with a stronger heat development than the first vacuum coating process.

9. The method of claim 8, wherein the first sublayer of the layer is deposited by magnetron sputtering and the second sublayer of the layer is deposited by evaporation.

10. The method of claim 1, wherein the layer is deposited with a layer thickness of less than 3 μm.

11. The method of claim 10, wherein the layer is deposited with a layer thickness of less than 1 μm.

12. The method of claim 1, wherein a ribbon-like flexible substrate is used as the flexible substrate.

13. The method of claim 12, wherein the layer is deposited by a roll-to-roll process.

14. The method of claim 1, wherein the electrically conductive material contains copper, indium, aluminum, tin, zinc, magnesium, and/or silver.

15. The method of claim 14, wherein the electrically conductive material includes copper.
